(19) United States
(12) Patent Application Publication
(10) Pub. No.: US 2026/0080111 A1
(43) Pub. Date: Mar. 19, 2026

(54) PREDICTIVE DURATION MODEL USING FIELD GEOMETRY

(71) Applicant: Raven Industries, Inc., Sioux Falls, SD (US)

(72) Inventors: Travis Allen Burgers, Sioux Falls, SD (US); Mohit Jain, Sioux Falls, SD (US); Kusha Kamarei, Sioux Falls, SD (US)

(21) Appl. No.: 19/333,085

(22) Filed: Sep. 18, 2025

Related U.S. Application Data
(60) Provisional application No. 63/696,442, filed on Sep. 19, 2024.

(51) Int. Cl. G06F 30/10; G06F 30/27

(52) U.S. Cl. CPC G06F 30/10; G06F 30/27

(57) ABSTRACT

A method may include receiving, using a processing unit, a request to calculate an estimated duration of an agricultural job, the request including an agricultural job identifier, issuing, using the processing unit, a data retrieval command using the agricultural job identifier, receiving field characteristics associated with a field, the field characteristics including a field shape value and an area of the field, encoding, using the processing unit, the field characteristics into a data structure configured to be input into a job duration machine learning model, executing, using the processing unit, the job duration machine learning model using the data structure, after executing the job duration machine learning model, accessing an output of the job duration machine learning model, the output associated with the estimated duration of the agricultural job, and transmitting, using the processing unit, the estimated duration and the job identifier to an agricultural job scheduling system.

### CROSS-REFERENCE TO RELATED APPLICATIONS

This application claims the benefit of priority to U.S. Provisional Application Ser. No. 63/696,442, filed Sep. 19, 2024, which is hereby incorporated in its entirety.

### BACKGROUND

Agricultural fields are subject to various jobs aimed at promoting plant growth, maintenance, and crop production. These jobs may include planting seeds or seedlings, applying fertilizers and pesticides, managing irrigation and drainage, pruning and training crops, harvesting, and preparing land through tillage and other forms of soil manipulation.

Each job may use specific equipment and techniques tailored to the cultivated crop type and the field's characteristics. For example, planting and harvesting operations typically involve specialized machinery such as tractors, seeders, combines, and harvesters. Soil-related jobs like tillage may employ different implements, including plows, cultivators, and disc harrows.

### BRIEF DESCRIPTION OF THE DRAWINGS

In the drawings, which are not necessarily drawn to scale, like numerals may describe similar components in different views. To easily identify the discussion of any particular element or act, the most significant digit or digits in a reference number refer to the figure number in which that element is first introduced. Like numerals having different letter suffixes may represent different instances of similar components. Some embodiments are illustrated by way of example, and not limitation, in the figures of the accompanying drawing.

FIG. 1 is a block diagram illustrating an example operating environment of an application server, according to various examples.

FIG. 2 is a block diagram illustrating example pipelines training and using a job duration machine learning model, according to various examples.

FIG. 3 is an illustration of different field complexities, according to various examples.

FIG. 4 is an example user interface for generating a job duration estimate, according to various examples.

FIG. 5 illustrates a flowchart of an example method to generate a job duration estimate, according to various examples.

FIG. 6 is a block diagram illustrating a machine in the example form of computer system 600, within which a set or sequence of instructions may be executed to cause the machine to perform any one of the methodologies discussed herein, according to various examples.

### DETAILED DESCRIPTION

The accuracy of many systems is only as good as the accuracy of the inputs provided to the systems. For example, to efficiently schedule resources (e.g., equipment, materials, operators, etc.) used for agricultural jobs, one factor is the duration of the agricultural job. If an agricultural job is expected to take 90 minutes but takes 120 minutes, other jobs scheduled to be performed on the same field are delayed and may not be completed. Additionally, agricultural jobs in other fields may have been expecting to use equipment that is now unavailable due to the incorrect job duration estimate.

Conversely, if an agricultural job ends up taking less time than estimated (e.g., 90 minutes instead of the expected 120 minutes), then resources that were previously allocated for the longer duration are unnecessarily committed and may be idle, while other jobs in need of those resources are delayed or unable to proceed. This inefficient allocation can lead to wasted resources and decreased productivity.

Estimating an agricultural job's duration is a complicated, technical task due to the number and variability of factors that may influence the job. These factors include field characteristics such as size, shape, and soil type; crop conditions like type, health, and growth stage; weather conditions including temperature, precipitation, and wind; equipment specifications such as type, capacity, and efficiency; operator experience and skill level, and task complexity and variability.

Reliance on human input is known to create inaccurate outputs due to factors such as subjective judgment and bias, limited knowledge or understanding of the specific job requirements, inability to accurately account for all relevant variables and their interactions, and human error in data entry or calculation. Limiting the number of options and inputs provided to the system may reduce the likelihood of an inaccurate estimate by minimizing the complexity and variability of the factors involved.

Given the above problems in existing scheduling systems, the described predictive model for estimating job durations in agricultural field operations overcomes several limitations of prior methods. One improvement is using a Field Shape Value (FSV) derived from field area and perimeter, which captures the complexity of a field's shape and its impact on operation time. Unlike methods that may rely on acreage or elevation variance alone, FSV provides a more accurate representation of a field's complexity. This metric enables better predictions tailored to each field's unique characteristics. Furthermore, the job duration machine learning model uses more nuanced weather data than simply average weather for a day. For example, the machine learning model uses historical weather conditions (e.g., the weather on the day(s) before the job data) and predicted weather conditions for a job's date.

The machine learning model is designed with efficiency in mind. It recognizes that as the number of inputs increases, the computational cost of running and training the model also increases. To address this, the model reduces the number of possible categories when possible. For instance, instead of using fifty geographic regions, a smaller number such as three, may be used. This reduction not only cuts computational costs but also simplifies the model, making it more practical and efficient.

Another improvement concerns the user interface for inputting information relevant to the job duration machine learning model. One problem with presenting too many user interface options is that users may mindlessly click through options to find an answer quickly or not know the answer. The resulting duration estimates using such an interface would be inaccurate. To address this problem, the described user interface will automatically retrieve data for use by the job duration machine learning model. Sometimes, the retrieved data may not even be displayed to the user. In other instances, the retrieved inputs may be displayed for overriding by a user.

To achieve this improvement, the data may be retrieved by entering an agricultural job identifier (JID) into the user interface. When users enter their JID, a system may retrieve relevant information from linked databases or APIs, such as job parameters, field characteristics, weather history, and machine specifications. This automated data retrieval saves time and ensures consistency and accuracy in the inputs used by the job duration machine learning model.

Having a more accurate job duration provides improvements to other systems as well. For example, using accurate job duration estimates in scheduling autonomous vehicles for agricultural tasks may provide benefits by optimizing the allocation of resources and minimizing delays. With an accurate estimate of task duration, farmers may avoid scheduling multiple vehicles to arrive at a task location only to find that one vehicle will be idle while another is completing its work. This inefficiency wastes fuel and may increase maintenance costs due to unnecessary wear on engines and other components. By scheduling autonomous vehicles based on accurate job duration estimates, managers may reduce the likelihood of such delays and inefficiencies.

The following description outlines specific examples to provide a thorough understanding of various inventive aspects. It will be evident, however, to one skilled in the art that the present invention may be practiced without these specific details. References in the specification to “one example,” “an example,” “an illustrative example,” etc., indicate that the example described may include a particular feature, structure, etc. Still, every example may not necessarily include that particular feature. Additionally, such phrases do not imply a single example, and the features may be incorporated into other examples described. It may be appreciated that lists in the form of “at least one A, B, and C” may mean (A); (B); (C): (A and B); (B and C); or (A, B, and C). Similarly, items listed in the form of “at least one of A, B, or C” can mean (A); (B); (C): (A and B); (B and C); or (A, B, and C). Furthermore, using such phrases does not negate the possibility of other options (e.g., (D)).

Throughout this disclosure, components may perform electronic actions in response to different variable values (e.g., thresholds, user preferences, etc.). As a matter of convenience, this disclosure does not always detail where the variables are stored or how they are retrieved. In such instances, it may be assumed that the variables are stored on a storage device (e.g., Random Access Memory (RAM), cache, hard drive) accessible by the component via an Application Programming Interface (API) or other program communication method. Similarly, the variables may be assumed to have default values should a specific value not be described. End-users or administrators may use user interfaces to edit the variable values.

In various examples described herein, user interfaces are described as being presented to a computing device. The presentation may include data transmitted (e.g., a hypertext markup language file) from a first device (such as a web server) to the computing device for rendering on a display device of the computing device via a web browser. Presenting may separately (or in addition to the previous data transmission) include an application (e.g., a stand-alone application) on the computing device generating and rendering the user interface on a display device of the computing device without receiving data from a server.

Furthermore, the user interfaces are often described as having different portions or elements. Although in some examples, these portions may be displayed on a screen simultaneously, in others, the portions/elements may be displayed on separate screens such that not all portions/elements are displayed simultaneously. Unless explicitly indicated as such, the use of “presenting a user interface” does not infer either one of these options.

Additionally, the elements and portions are sometimes described as being configured for a particular purpose. For example, an input element may be configured to receive an input string, a selection from a menu, a checkbox, etc. In this context, “configured to” may mean presenting a user interface element capable of receiving user input. “Configured to” may additionally mean computer executable code processes interactions with the element/portion based on an event handler. Thus, a “search” button element may be configured to pass text received in the input element to a search routine that formats and executes a structured query language (SQL) query to a database.

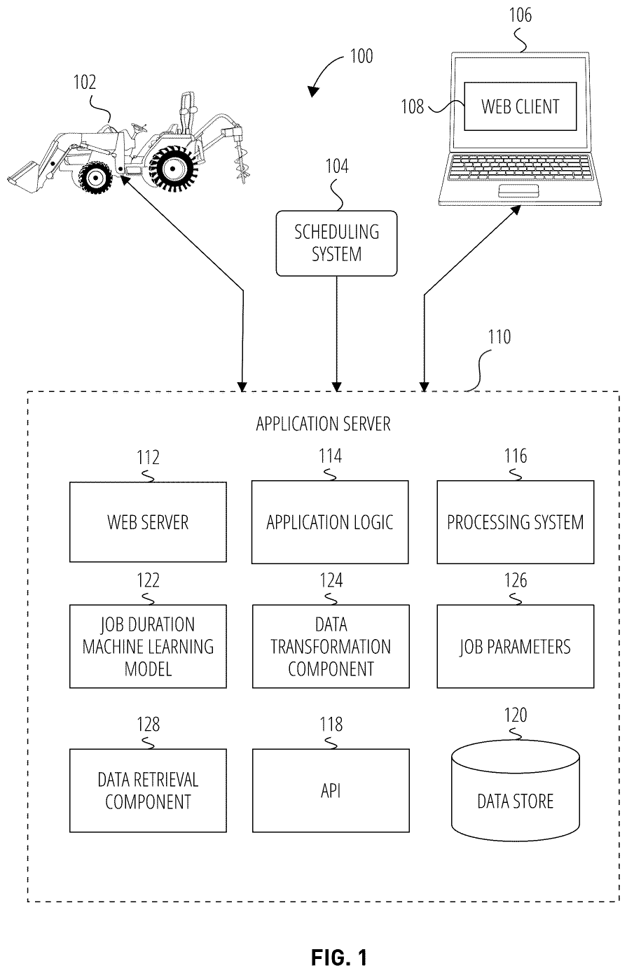

FIG. 1 is a block diagram 100 illustrating an example operating environment of an application server, according to various examples. The diagram includes a piece of agricultural equipment 102, a scheduling system 104, a client device 106, a web client 108, and an application server 110. The application server 110, in various examples, includes a web server 112, an application logic 114, a processing system 116, an API 118, a data store 120, a job duration machine learning model 122, a data transformation component 124, a job parameters 126, and a data retrieval component 128. In various examples, the agricultural equipment 102 (e.g., via an onboard computing device), scheduling system 104, and client device 106 may digitally interact over a network with application server 110 to receive or request job duration estimates.

Application server 110 is illustrated as a set of separate elements (e.g., components, logic, systems, etc.). However, the functionality of multiple individual elements may be performed by a single element. An element may represent computer program code executable by processing system 116. The program code may be stored on a storage device (e.g., data store 120) and loaded into the memory of the processing system 116 for execution. Portions of the program code may be executed in parallel across multiple processing units. A processing unit may be a grouping of one or more cores of a general-purpose computer processor, a graphical processing unit, an application-specific integrated circuit, or a tensor processing core. Furthermore, the grouping may operate on a single device or multiple devices (either collocated or geographically dispersed). Accordingly, code execution using a processing unit may be performed on a single device or distributed across multiple devices. In some examples, using shared computing infrastructure, the program code may be executed on a cloud platform (e.g., MICROSOFT AZURE® and AMAZON EC2®).

Client device 106 may be a computing device which may be, but is not limited to, a smartphone, tablet, laptop, multi-processor system, microprocessor-based or programmable consumer electronics, game console, set-top box, or other device that a user utilizes to communicate over a network. In various examples, a computing device includes a display module (not shown) to display information (e.g., specially configured user interfaces). In some embodiments, computing devices may comprise one or more of a touch screen, camera, keyboard, microphone, or Global Positioning System (GPS) device.

Agricultural equipment 102 may include, but is not limited to, tractors, plows, harrows, seed drills, combines, balers, irrigation systems, sprayers, cotton pickers, rice transplanters, and vineyard pruners. In various examples, agricultural equipment 102 may include one or more computing devices and sensors. These computing devices could be specialized controllers for specific tasks, while the sensors may include GPS for location tracking, weather sensors for monitoring environmental conditions, and soil sensors for measuring soil moisture and nutrient levels. These devices and sensors may aid in performing the agricultural job.

The agricultural equipment 102, the scheduling system 104, client device 106, and application server 110 may communicate via a network (not shown). The network may include local-area networks (LAN), wide-area networks (WAN), wireless networks (e.g., 802.11 or cellular network), Public Switched Telephone Network (PSTN), ad hoc networks, cellular, personal area networks or peer-to-peer (e.g., Bluetooth®, Wi-Fi Direct), or other combinations or permutations of network protocols and network types. The network may include a single Local Area Network (LAN), Wide-Area Network (WAN), or combinations of LANs or WANs, such as the Internet.

The scheduling system 104 may be a system configured to assign agricultural jobs to specific time slots based on estimates of job duration as received from the application server 110. The scheduling system 104 may consider various factors, such as the availability of resources, including equipment and personnel, and the estimated duration of each job.

Upon receiving an estimate of job duration from the job duration machine learning model 122, the scheduling system 104 may calculate the optimal time for assigning a particular agricultural job to a specific set of resources. This calculation may be based on factors such as equipment availability and operating personnel.

In some examples, the communication may occur using an application programming interface (API) such as API 118. An API provides a method for computing processes to exchange data. A web-based API (e.g., API 118) may permit communications between two or more computing devices, such as a client and a server. The API may define a set of HTTP calls according to Representational State Transfer (RESTful) practices. For example, A RESTful API may define various GET, PUT, POST, and DELETE methods to create, replace, update, and delete data stored in a database (e.g., data store 120) The application server 110 may also use APIs provided by external services. The application server 110 may utilize APIs provided by external services to obtain specific types of data. For example, the scheduling system 104 may use an API of a logistics service to obtain information about available agricultural equipment for a particular agricultural job. The API may also be used to retrieve sensor readings from field-based equipment or agricultural equipment. The data retrieval component 128 may use an API of a weather service to obtain current and forecasted weather data, which can then be used in conjunction with sensor readings to determine current or predicted parameters for an agricultural job. The data may be used as input to job duration machine learning model 122 in various examples.

Application server 110 may include web server 112 to enable data exchanges with client device 106 via web client 108. Although generally discussed in the context of delivering webpages via the Hypertext Transfer Protocol (HTTP), other network protocols may be utilized by web server 112 (e.g., File Transfer Protocol, Telnet, Secure Shell, etc.). A user may enter a uniform resource identifier (URI) into web client 108 (e.g., the INTERNET EXPLORER® web browser by Microsoft Corporation or SAFARI® web browser by Apple Inc.) that corresponds to the logical location (e.g., an Internet Protocol address) of web server 112. In response, web server 112 may transmit a web page rendered on a client device's display device (e.g., a mobile phone, desktop computer, etc.).

Additionally, web server 112 may enable users to interact with one or more web applications provided in a transmitted web page. A web application may provide user interface (UI) components rendered on a display device of the client device 106. The user may interact (e.g., select, move, enter text into) with the UI components, and, based on the interaction, the web application may update one or more portions of the web page. A web application may be executed in whole or in part locally on client device 106. The web application may populate the UI components with data from external or internal sources (e.g., data store 120) in various examples.

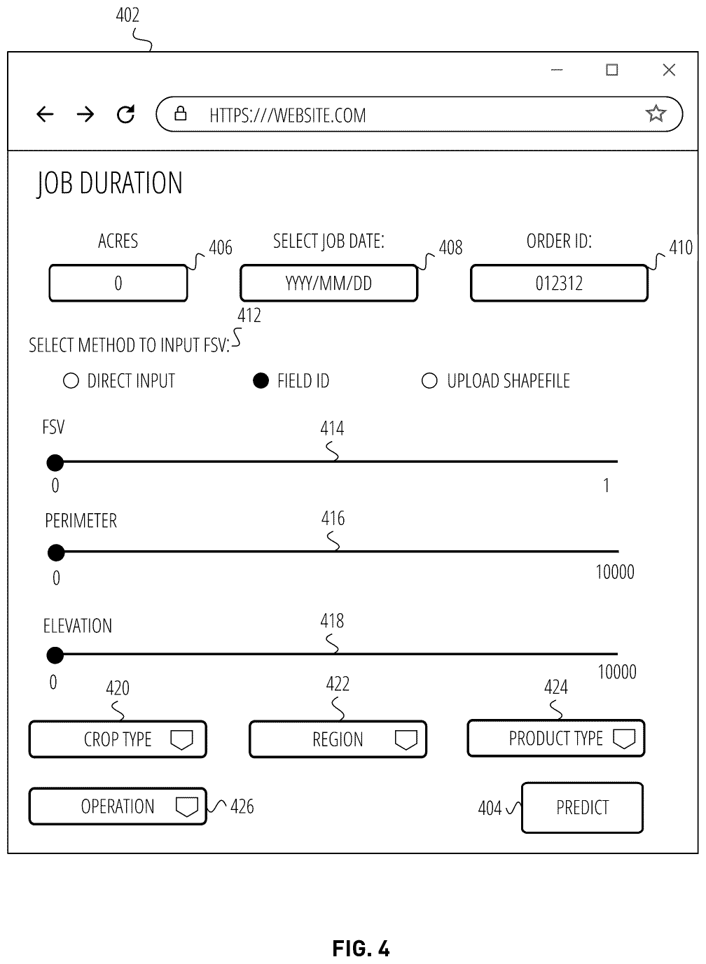

In various examples, the web application includes a user interface configured to facilitate generating a duration estimate for an agricultural job. The user interface may be presented on a client device (e.g., client device 106) or a computing device that is part of agricultural equipment 102. The user interface may be configured in different ways depending on the stored role of a user or the user's preferences. For example, there may be a default user role, an advanced user role, and an administrator role. For the default user, a standard set of user interface elements may be displayed (e.g., a job identifier input and a field identifier input) with additional input or output elements displayed for the advanced and administrator roles. An example user interface is presented and discussed in more depth in FIG. 4.

The web application may be executed according to application logic 114. Application logic 114 may use the various elements of application server 110 to implement the web application. For example, application logic 114 may issue API calls to retrieve or store data from data store 120 and transmit it for display on the client device 106. Similarly, data entered by a user into a UI component may be transmitted using API 118 back to the web server. Application logic 114 may use other elements (e.g., job duration machine learning model 122, data transformation component 124, job parameters 126, etc.) of application server 110 to perform functionality associated with the web application as described further herein.

For example, the web application may, based on a received job identifier in the user interface, use data retrieval component 128 to obtain job parameters from job parameters 126, quantify the job parameters into a vector format using data transformation component 124, and initiate execution of the job duration machine learning model 122. The remaining figures of this disclosure discuss more detailed example implementations of job duration machine learning model 122, data retrieval component 128, and data transformation component 124.

Data store 120 may store data used by application server 110 (e.g., job parameters 126, agricultural job data structures, field shape information, etc.) Data store 120 is depicted as a singular element but may be multiple data stores. The data store 120 may include several databases of varying model architectures such as, but not limited to, a relational database (e.g., SQL), a non-relational database (NoSQL), a flat-file database, an object model, a document details model, graph database, shared ledger (e.g., blockchain), or a file system hierarchy. Data store 120 may store data on one or more storage devices (e.g., a hard disk, random access memory (RAM), etc.). The storage devices may be in standalone arrays, part of one or more servers, and located in one or more geographic areas.

Data structures may be implemented in several ways depending on the programming language of an application or the database management system used by an application. For example, if C++ is used, the data structure may be implemented as a struct or class. In the context of a relational database, a data structure may be defined in a schema. “Associated” in the context of linking a job identifier to a field identifier (or other data linkages described herein) may be implemented differently depending on the underlying database system. For example, in a relational database management system (RDBMS), “associated” may refer to the relationship between tables. The relationship could be one-to-one, one-to-many, or many-to-many, established through foreign key constraints. For example, in a one-to-many relationship, a record in Table A (e.g., a job table) may be associated with multiple records in Table B (e.g., a field table), using a foreign key in Table B that references the primary key in Table A.

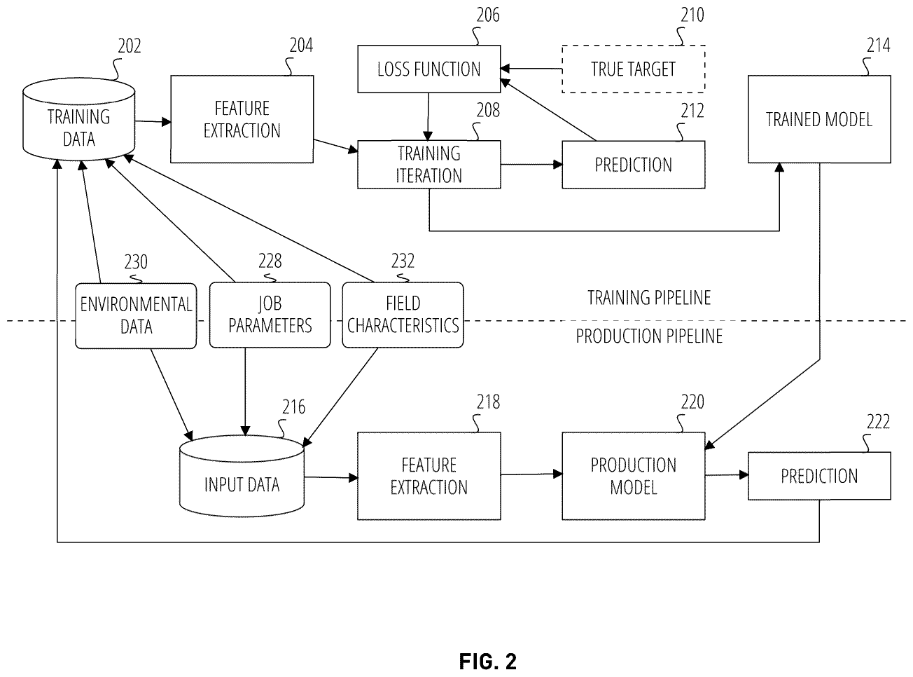

FIG. 2 is a block diagram illustrating example pipelines for training and using a job duration machine learning model, according to various examples. The job duration machine learning model may be job duration machine learning model 122 in various examples. Depending on the final machine learning model type used, more or fewer operations than those depicted may be executed. Machine learning encompasses different algorithms used to predict or classify a data set. In general terms, there are three types of ML algorithms: supervised learning, unsupervised learning, and reinforcement learning.

Supervised learning algorithms may make a prediction based on a labeled data set (job parameters associated with a job duration) and are generally used for classification, regression, or forecasting. Some examples of supervised learning algorithms are Naïve Bayes, Support Vector Machines, Linear Regression, Logistic Regression, Decision Trees, Random Forests, and K-Nearest Neighbor. Unsupervised learning algorithms may use an unlabeled data set (e.g., looking for clusters of similar data based on common characteristics). An example of an unsupervised learning algorithm is K-mean clustering.

Reinforcement learning algorithms generally make a prediction/decision, and then a user determines whether the prediction/decision was right—after which the machine learning model may be updated. This type of learning may be helpful when a limited input data set is available.

Neural networks (also called artificial neural networks (ANN)) are a subset of ML algorithms that may be used to solve problems similar to those of the machine learning algorithms listed above. ANNs are computational structures that are loosely modeled on biological neurons. Generally, ANNs encode information (e.g., data) via weighted connections (e.g., synapses) between nodes (e.g., neurons). ANNs have many AI applications, such as automated perception (e.g., computer vision, speech recognition, contextual awareness, etc.), automated cognition (e.g., decision-making, logistics, routing, supply chain optimization, etc.), automated control (e.g., autonomous cars, drones, robots, etc.), among others. The weights may be updated using a gradient descent technique during the training process.

One aspect of machine learning model design is selecting the type of machine learning model and its hyperparameters. Hyperparameters are machine learning models'components that control the model's structure or behavior. They include parameters such as learning rate, number of trees in random forests, depth of decision trees, regularization strength, and others. Unlike traditional parameters (also known as coefficients), hyperparameters are not learned from data during training but are set before training begins. An AutoML (automated machine learning) system may help determine optimal hyperparameter settings.

One step in using an AutoML system is to define the search space for each hyperparameter, specifying the range of values or a set of possible options. The next step may be to select an appropriate search method, such as a systematic approach like grid search (exhaustively trying all combinations), a more efficient random search, Bayesian optimization that uses prior probabilities to intelligently sample from the space, or evolutionary algorithms that evolve a population of candidate hyperparameters over generations.

For each combination of hyperparameters sampled by the search method, an instance of the machine learning model is trained using the training data. The model's performance is then evaluated on a validation set (or using techniques like cross-validation) to obtain an estimate of its generalization ability. Based on the evaluation results, the AutoML system updates its understanding of the hyperparameter space and decides which parameters to sample next.

The training data 202 may include data on past agricultural jobs. In various examples, the training data 202 may be stored in a database such as data store 120 in FIG. 1. The data may include environmental data 230, job parameters 228, and field characteristics 232. The environmental data 230 may include but is not limited to, weather conditions (e.g., precipitation type, precipitation rate, wind speed, temperature) before the job, weather conditions at the time of the job, soil moisture levels, etc. The job parameters 228 may include but are not limited to, the type of agricultural job (e.g., seeding, harvesting, irrigation, fertilizing, pest control spraying, etc.), the type and model of equipment used during the agricultural job, type of implement, whether a fixed or variable spray rate will be used, weight of a crop, date the agricultural job was performed, geographic location of the agricultural job, etc. The job parameters 228 may also include the number of pieces of agricultural equipment used. For example, for large agricultural jobs, there may be more than one piece of equipment used, which impacts the duration to complete the job. In such instances, the job parameters 228 may include the type and number of each piece of agricultural equipment used for the job. Furthermore, the job parameters 228 may include the length of time each piece of agricultural equipment was used for the past job (e.g., 100 minutes for one machine, and 45 minutes for another).

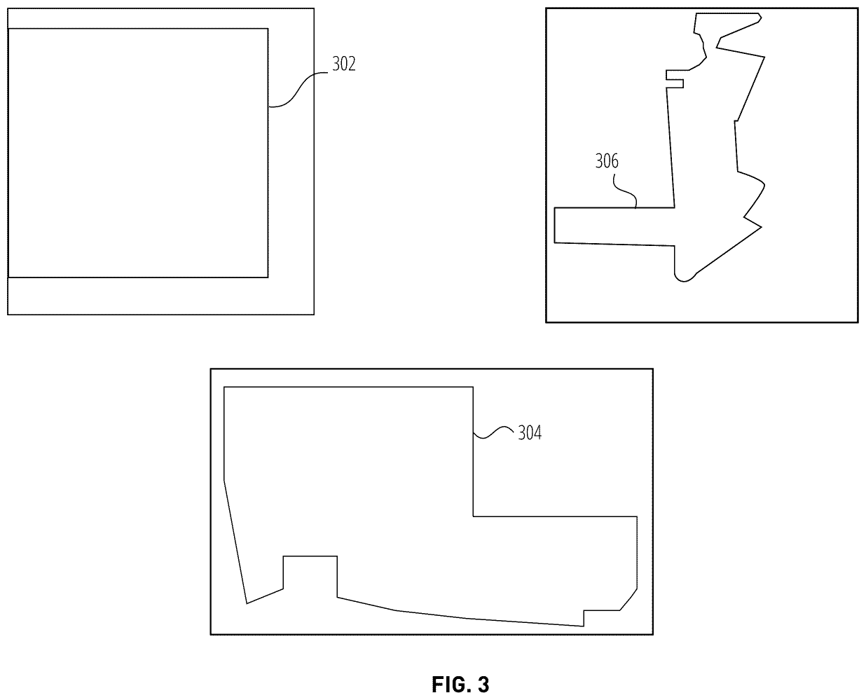

The field characteristics 232 may include but are not limited to, an area (e.g., acreage) of the field on which the agricultural job was performed, elevation data (e.g., average above sea level elevation, maximum elevation, minimum elevation, etc.), passable or impassable obstacles, a perimeter of the field, and a field shape value (discussed further in FIG. 3).

Regarding FIG. 2, the training pipeline may begin by retrieving data points of an agricultural job entry from training data 202 that includes the environmental data, job parameters, and field characteristics for a previously completed job labeled with the duration (e.g., in minutes) it took to complete the agricultural job. The training data for the agricultural job may be stored in an agricultural job data structure that includes data fields for each data point in the environmental data, job parameters, field characteristics, and job duration.

Feature extraction 204 may include normalization and quantification of the training data 202. The feature extraction 204 may be performed using a data transformation component such as data transformation component 124 of FIG. 1. Different data features may use different techniques for normalization and quantification. For example, for numerical data such as soil moisture data, temperature readings, etc., a min-max normalization may be used such as X_norm=(X−X_min)/(X_max−X_min) or standardization such as norm=(X−μ)/σ, where μ is mean and σ is the standard deviation of the feature. Some features may use the raw data (e.g., field acreage). Another technique may use interquartile range (IQR) normalization or Winsorization to reduce the impact of outliers. For example, IQR normalization scales the data within a certain percentage (e.g., 90%) of the observations.

When a data point is not numerical, the data point may be encoded into a numerical format. For example, encoding may be used for job type (e.g., seeding, harvesting, irrigation, fertilizing, pest control spraying), the type and model of equipment used during the agricultural job, the date the agricultural job was performed, the geographic location of the agricultural job, etc. One encoding type is One-Hot Encoding, where each category is represented as a binary vector and each category is assigned a unique index. For example, the type of agricultural job can be represented as a binary vector: [0, 1, 0, . . . ] for seeding, [1, 0, 0, . . . ] for harvesting, etc. Thus, there is a binary vector with a ‘1’ in the position corresponding to the category and ‘0’s elsewhere. One-hot encoding may also be used for precipitation type (e.g., rain may be [1, 0, 0 . . . ] and snow may be [0, 1, 0, . . . ]).

Another technique may be labeled encoding, where each category is assigned a value. For example, a geographic region of the job may be encoded as 0 for a low-yield region, a 1 for a medium-yield region, and a 2 for a high-yield region. A lookup table may be used to determine which state, zip code, etc., corresponds to the different yield regions. The date of the agricultural job may be encoded into a two-element vector, such as the month of the year (e.g., January=1, February=2) and the day of the month (e.g., 1=0, 15=14, . . . , 31=30. Another method of encoding the date may be to assign an integer value to each unique date in chronological order. For example, Jan. 1, 2022,=0, Jan. 2, 2022,=1, . . . , Dec. 31, 2022,=365.

To prepare the agricultural data for processing, the encoded features from the environmental data 230, job parameters 228, and field characteristics 232 are concatenated into a single vector or matrix (referred to as a feature vector) as part of a training iteration 208. A training iteration 208 is a step in the machine learning pipeline, where trained model 214 is executed with the feature vector created from the encoded data to produce an output prediction 212. In this context, the prediction 212 may be an estimated job duration, providing a quantitative forecast for future agricultural jobs.

The loss function 206 is used to evaluate the predicted job duration's accuracy. The loss function 206 measures the difference between the predicted outcome (i.e., the estimated job duration) and the true target 210, which in this case represents the actual job duration extracted from the training data 202. The loss function 206 may be a Mean Squared Error (MSE) or Cross-Entropy Loss in various examples.

A training iteration 208 includes executing the machine learning model with the feature vector and obtaining prediction 212. The prediction 212 may be an estimated job duration. The prediction 212 may be compared to the true target 210 (e.g., the actual job duration from training data 202) using the loss function 206. Then, the trained model 214 may be updated, and another training iteration 208 may be performed (e.g., the next entry of past agricultural jobs).

The trained model 214 may then be updated based on the results obtained from the loss function 206. The update process involves adjusting the model's parameters (e.g., coefficient weights) to minimize the difference between the predicted and true target values. This iterative refinement of the model's parameters allows it to learn from its mistakes and improve its predictive capabilities over time.

Depending on the architecture, different techniques may be used to update trained model 214. For example, gradient descent-based optimization algorithms like Stochastic Gradient Descent (SGD) may be used for neural networks to update node weights and biases iteratively during backpropagation. A logistical regression model may use gradient descent or a maximum likelihood estimation to update its coefficients such as by assuming a Gaussian distribution for numerical inputs. After a stopping condition, such as the number of epochs for neural network or convergence, the model may be considered trained for use in the production pipeline as production model 220.

Turning to the production pipeline of FIG. 2, input data 216 may include environmental data 230, job parameters 228, and field characteristics 232 of a future agricultural job. The input data 216 may result from a user requesting a job duration via a user interface of a website (e.g., as served from application server 110) and data retrieved (e.g., using data retrieval component 128). In various examples, the feature extraction 218 process is performed similarly to feature extraction 204. Accordingly, feature extraction 218 produces an input feature vector with quantitative values. The input feature vector is input into the production model 220, which, after execution, produces prediction 222. Executing the production model 220 may use a processing system (e.g., processing system 116) whereby the values in the input feature vector are processed based on the architecture of the production model 220.

Accordingly, if production model 220 is a neural network, there may be a single output node for prediction 222 representing the number of estimated minutes for the agricultural job. In other examples, there may be output nodes for each possible duration minute (e.g., 360 nodes if the maximum duration is expected to be 6 hours). Each node may have a value corresponding to the probability it is the correct job duration. For example, if the 55th node has a value of 0.82, it may be read as there is an 82% probability that the job will take 55 minutes. The node with the highest value may represent the highest likelihood of the correct job duration.

Over time, the accuracy of machine learning models can degrade due to changes in underlying patterns or new data distributions. To maintain an accurate predictive model, a continuous improvement method may be used that updates and refines the model periodically. For example, each week (or another set period), the predictions made using prediction 222 are stored alongside their respective input features in a dedicated data store. As agricultural jobs are completed, the actual job durations are appended to these entries.

Then, production model 220's accuracy is assessed by comparing its predictions with the actual job durations stored in the data store. If the average error between predicted and actual durations exceeds a predefined threshold (e.g., ±5 minutes), it triggers an automated retraining process. This threshold may be set to ensure that the model maintains a high level of accuracy while minimizing unnecessary retraining cycles.

When a retraining condition is met (e.g., the average error exceeds a threshold), the training pipeline in FIG. 2 may be rerun using the new entries as additional training data. Thus, any new patterns or changing conditions may be incorporated into the job duration machine learning model weights.

Furthermore, this approach allows for incorporating new features or improving existing ones as needed. For instance, if a new type of machinery is introduced on the farm, relevant data can be integrated into the training process, allowing the model to learn and adapt to these changes. By combining continuous monitoring, evaluation, and refinement, the machine learning pipeline ensures that it remains accurate for optimizing agricultural operations.

There may be different versions of the job duration machine learning model in various examples. For instance, agricultural jobs may initially be classed based on field size. Thus, there may be “small,” “medium,” and “large” models trained on data corresponding to different field size (e.g., based on acreage) ranges. Furthermore, the data used to train the various models may differ as some data points may not be needed for fields of a certain size. For example, during the training process, it may be determined that the impact on temperature for small fields is not significant (e.g., the model's accuracy stays within 1% the same). Thus, the small model may forgo using temperature as input. In doing so, the model may be executed on less powerful computing systems or executed faster, given the same hardware. Similarly, additional factors may be added to the medium and large models. For example, the agricultural equipment capacity may be used as a factor in the medium and large models.

Furthermore, a machine learning model for predicting tender truck trips may be trained using environmental data 230, job parameters 228, and field characteristics 232, but that information is correlated with tender truck information as the prediction 212. Thus, given a set of input data, the machine learning model would output the number of tender truck trips. The output of the tender truck trips prediction model may serve as an additional input feature for the job duration machine learning model. By considering the anticipated number of tender truck trips alongside other parameters like environmental conditions and equipment used, the job duration machine learning model could then account for potential delays or efficiencies introduced by logistics factors. This interconnected approach enables the job user intent machine learning model to generate more informed and precise predictions about agricultural job durations.

The production model 220 may be utilized in real-time scenarios to provide dynamic updates and estimates during the execution of agricultural jobs. As a job progresses, the production model 220 may be executed at regular intervals (or on demand), such as every five minutes, to generate updated estimates of the remaining time for job completion. The production model 220 may incorporate real-time data from sensors on agricultural equipment, weather updates, and other relevant sources to generate predictions. This real-time data may be encoded into the input vector and used as input to the production model 220 allowing it to account for changing conditions that may affect job duration.

Furthermore, the production model 220 may be employed to simulate various scenarios involving the addition or removal of agricultural equipment from the job. For instance, an operator may input hypothetical changes to the equipment configuration, such as adding an extra combine harvester or replacing a piece of equipment with a higher-capacity model. The production model 220 may then generate new duration estimates based on these hypothetical scenarios, allowing operators to make informed decisions about resource allocation. The simulated scenarios may be generated during a job as well, allowing the operator to make decisions as to whether or not to add additional equipment.

As discussed previously, the input vector for production model 220 may include fields for equipment types, quantities, and capacities. The model may be trained on historical data that includes jobs completed with various equipment configurations, enabling it to accurately predict the impact of equipment changes on job duration.

The production model 220 may be utilized in various real-time scenarios to provide dynamic updates and estimates during the execution of agricultural jobs. In addition to regular interval updates, the production model 220 may be employed to address specific customer concerns and operational challenges.

For instance, if a storm is predicted for the following day, users may be interested in options to complete the job within the current day. In such cases, the production model 220 may be used to simulate the impact of adding an additional machine to the current operation. The model may generate an updated job duration estimate that accounts for the extra equipment. The updated job duration estimate may be transmitted to the user, allowing the user to make decisions about resource allocation.

Moreover, the production model 220 may be adapted to handle unforeseen events such as equipment breakdowns. In a scenario where three machines are initially working on a job and one experiences a breakdown, the model may be executed to recalculate the job duration based on the reduced equipment capacity. This real-time adjustment may be provided to operators and scheduling systems, enabling them to assess the impact of the breakdown and potentially implement mitigation strategies.

FIG. 3 is an illustration of different field complexities, according to various examples. FIG. 3 includes three example fields: field shape 302, field shape 304, and field shape 306.

A Field Shape Value (FSV) serves as a proxy for a field's complexity, which may influence various aspects of agricultural operations, such as job duration. The FSV provides a more accurate representation of a field's characteristics than using area or perimeter alone. This metric enables better predictions tailored to each field's unique complexities.

Different methods may be employed to calculate FSV, but in various examples, it is based on a combination of perimeter and area values. An example formula may be: Using this formulation, FSV ranges from 0.1 (highly irregular) to 1 (perfect circle), with a square being 0.79. With regard to FIG. 3, the FSV of field shape 302 may be 0.79, the FSV of field shape 304 may be 0.46, and the FSV of field shape 306 may be 0.24.

The values for the area and perimeter may be received as direct user input, such as through a user interface (e.g., as presented by web server 112 in FIG. 1) or retrieved from a database based on a job identifier and field identifier. In various examples, the area and perimeters may be parsed from a shapefile, which includes labeled polygons containing the information. The shapefile, a vector data storage format using geographic information system (GIS) information, provides a standardized way to store spatial data, including perimeter and area measurements. A shapefile may include one or more polygons outlining the fields.

FIG. 4 is an example user interface 402 for generating a job duration estimate, according to various examples. The user interface 402 may be presented by a user logging into an agricultural job system that includes elements such as discussed in application server 110 of FIG. 1. The user interface 402 is illustrated as including a predict button 404, a size input 406, a date input 408, an order input 410, an FSV input type selector 412, an FSV slider 414, a perimeter slider 416, an elevation slider 418, a crop type selector 420, a region selector 422, a product type selector 424, and an operation selector 426.

The arrangement, labeling, and number of user interface elements are one example of an interface for generating a job duration estimate and other arrangements may be used. For example, certain user identifiers may be associated with different user interface arrangements based on a role. A default user interface may present the date input 408, order input 410, and the field ID option for FSV input type selector 412. An advanced user interface may present default user interface fields plus the manual entry in FSV input type selector 412. An administration user interface may include all elements shown in user interface 402. The type of user interface may be selected when a user logs into the agricultural job system according to their associated user interface type.

In various examples, some user interface elements may automatically update based on user interaction with other user interface elements. Thus, if a user enters a job identifier in order input 410, one or more of the size input 406, date input 408, FSV slider 414, perimeter slider 416, elevation slider 418, crop type selector 420, region selector 422, product type selector 424, operation selector 426 may update to reflect their respective values according to the job identifier. For example, a query may made to a database to retrieve an agricultural job data structure that stores the job parameters as discussed previously (e.g., job parameters 228 in FIG. 2) and field characteristics (e.g., field characteristics 232 in FIG. 2) that include the values for the user interface elements. In various examples, some user interface elements may be presented but not editable by the user. For example, in the default user interface, the crop type selector 420, region selector 422, product type selector 424, and operation selector 426 may automatically populate based on a job identifier but remain uneditable.

The FSV slider 414, when enabled using the direct input method of FSV input type selector 412, allows a user to adjust a field's corresponding FSV value. If the field ID method is used, another element may be presented to enter a field identifier. The field identifier may be used to query a database for field characteristics 232, including the FSV. The FSV input type selector 412 also allows a shapefile to be used to calculate the FSV. The elevation slider 418 is configured to receive the field's elevation (e.g., average elevation). The crop type selector 420 allows users to choose the specific crop being cultivated on the field. The region selector 422 enables users to specify the field's geographic location (e.g., state, zip code, province). The product type selector 424 permits users to select the type of agricultural product being applied on the field. Finally, the operation selector 426 allows users to choose the specific agricultural operation being performed on the field, such as planting, harvesting, or irrigation.

When the user clicks the predict button 404 in the user interface 402, the agricultural job system may generate a feature vector for inputting into a job duration machine learning model (e.g., job duration machine learning model 122). The feature vector may be generated as discussed in FIG. 2. For example, the job parameters for the feature vector may be accessed by parsing an agricultural job data structure associated with an entered job identifier.

In various examples, the user interface 402 may include additional input fields or dropdown menus that allow users to modify certain parameters and observe their impact on the estimated job duration. These changeable parameters may include the number of pieces of equipment and weather conditions.

For instance, the user interface 402 may present a dropdown menu or input field for specifying the number (and type) of pieces of agricultural equipment to be used for the job. This allows users to adjust the equipment quantity and see how it affects the estimated duration. The system may update the job duration estimate in real-time as the user modifies this parameter, providing immediate feedback on how equipment allocation impacts the overall job timeline.

Similarly, the user interface 402 may include weather-related input fields or sliders that enable users to modify forecasted weather conditions. These may include temperature ranges, precipitation probabilities, or wind speed estimates. As users adjust these weather parameters, the estimated job duration may be recalculated and displayed.

In various examples, the system may provide predefined scenarios or templates that users can select from, representing common combinations of equipment and weather conditions. These templates may serve as starting points for users to further customize and refine their job duration estimates based on specific field conditions and operational requirements.

The system uses various input fields and sliders in the user interface 402 to create the feature vector. For example, the system may retrieve values from the date input 408, order input 410, size input 406, crop type selected in crop type selector 420, region selected in region selector 422, product type selected in product type selector 424, and operation selected in operation selector 426. The value in order input 410 may be used to retrieve a field identifier associated with the job identifier.

However, the system may not always have access to all of this information. In some cases, additional data from external sources may be needed to complete the feature vector. For instance, based on the date input 408, the system may make API calls to weather services to retrieve predicted conditions such as temperature, precipitation type, precipitation amount, and wind speed. Similarly, the system may use APIs to obtain field conditions such as soil type, pH level, and nutrient content from databases or external services.

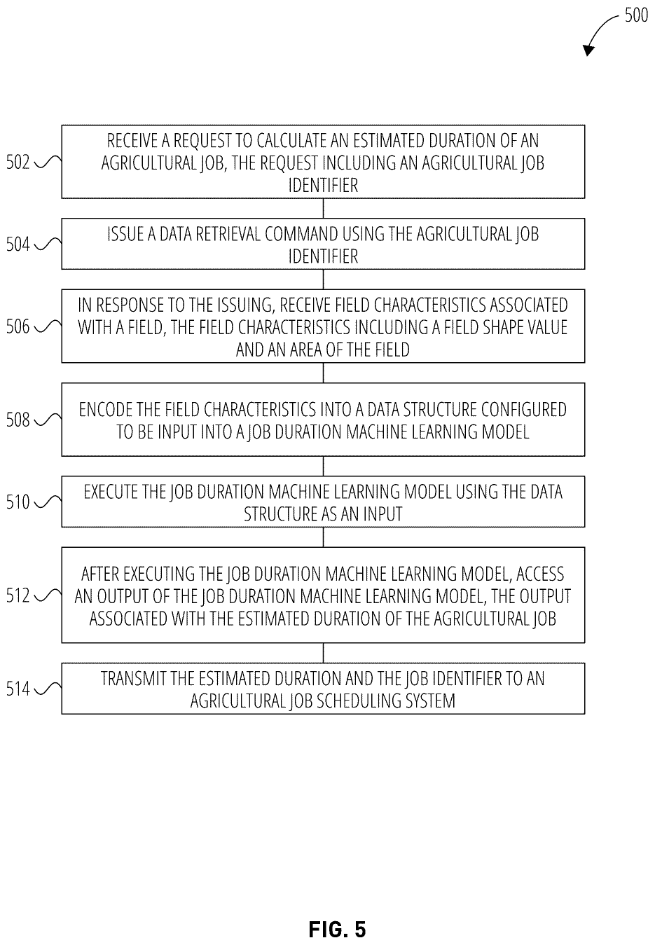

FIG. 5 illustrates a flowchart 500 of an example method to generate a job duration estimate, according to various examples. The method is represented as a set of blocks that describe operations 502 to 514. The method may be embodied in a set of instructions stored in at least one computer-readable storage device of a computing device. A computer-readable storage device excludes transitory signals. In contrast, a signal-bearing medium may include such transitory signals. A machine-readable medium may be a computer-readable storage device or a signal-bearing medium. A processing unit, which executing the set of instructions, may configure the processing unit to perform the operations illustrated in FIG. 5. The processing unit may instruct other component of a computing device to carry out the set of instructions. For example, the processing unit may instruct a network device to transmit data to another computing device or the computing device may provide data over a display interface to present a user interface. In some examples, performance of the method may be split across multiple computing devices using a shared computing infrastructure (e.g., the processing unit encompasses multiple distributed computing devices). In various examples, the depicted operations are performed at a server such as application server 110.

At operation 502, the method may include receiving a request to calculate an estimated duration of an agricultural job, the request including an agricultural job identifier. For example, the request may originate from agricultural equipment (e.g., agricultural equipment 102), an agricultural job scheduling system (e.g., a scheduling system 104), or a computing device (e.g., a client device 106), among others. The agricultural job identifier may correspond to an agricultural job data structure stored in a database (e.g., data store 120) of a server that receives the request (e.g., application server 110).

In various examples, the request to calculate the estimated duration of the agricultural job is a request for an estimated duration of an agricultural job in progress. For example, an automated process may execute such that real-time data is collected for the agricultural job every five minutes (or another interval), and an updated estimated duration may be generated and transmitted to an operator associated with the job.

In various examples, the request may be in response to a trigger event. For example, a system such as application server 110 may receive updates on the status of jobs in progress or weather forecast updates. A trigger event may be based on receiving (e.g., over API 118) a change in the operational status of a piece of agricultural equipment associated with the agricultural job identifier. The change may be that the piece of agricultural equipment has suffered a malfunction and is no longer operable or that the piece of agricultural equipment has suffered a failure such that it has a reduced efficiency to 50%. Another trigger event may be a change in predicted weather for a job. For example, if a thunderstorm is predicted for the next day, the output from the request for the estimate may include simulated scenarios of adding additional pieces of agricultural equipment to finish the job on the current day.

Trigger events may also relate to scheduling changes of an operator. For example, the application server 110 may receive an API call indicating an operator is no longer going to be available on the planned day of a job (e.g., tomorrow) but is available on the current day (e.g., today). Thus, a new estimated duration may be generated for the current day.

Another trigger may be a change in a job's priority. For example, if a job needs to be completed more quickly than before, a new estimated duration may be generated, assuming additional equipment is made available for the job.

In various examples, the method may further include presenting a user interface on a computing device including an agricultural job identifier input configured to receive the agricultural job identifier. The user interface may be one such as depicted in FIG. 4. The agricultural job identifier may be depicted as an order identifier in the user interface (e.g., order input 410).

At operation 504, the method may include issuing a data retrieval command using the agricultural job identifier. At operation 506, the method may include in response to the issuing, receiving field characteristics associated with a field, the field characteristics including a field shape value and an area of the field. In various examples, the field shape value may be stored as a value associated with the field. In other examples, the field shape value may be calculated based on the area of the field and the perimeter of the field (e.g., as stored in a database).

The issuing of operation 504 may include executing API calls or database query commands. The data retrieval command of operation 504 may include retrieving or calculating environmental data, job parameters, and field characteristics associated with the agricultural job identifier. The environmental data, job parameters, and field characteristics may include data such as described for environmental data 230, job parameters 228, and field characteristics 232 of FIG. 2.

For example, issuing may include executing an API call with a date and location associated with the agricultural job identifier. The date may be the planned date of the agricultural job and the location may be an address of the agricultural job. The API call may be issued to a weather service. Weather data may be received in response to the executing, including forecasted temperatures and precipitation type, and precipitation amounts.

In various examples, in response to the issuing of operation 504, job parameters associated with the agricultural job identifier may be retrieved (e.g., by querying the agricultural job data structure). The job parameters may be an operation type (e.g., planting) and an estimated number of tender truck trips for the agricultural job. The estimated number of tender truck trips may be based on the output of a machine learning mode using the data retrieved from operation 502.

In various examples, the method may include updating the user interface to include an operation user interface element based on the received agricultural job identifier. For example, an operation type may be received as the result of operation 506. Accordingly, an element such as operation selector 426 may be populated with the received operator type.

At operation 508, the method may include encoding the field characteristics into a data structure configured to be input into a job duration machine learning model. In various examples, the method may include selecting the job duration machine learning model from a plurality of job duration machine learning models based on the area of the field. For example, a first job duration machine learning model may be used for field areas of less than 10 acres, a second job duration machine learning model for areas between 11 and 50 acres, and a large job duration machine learning model for fields having an area over 100 acres.

The encoding may include encoding the weather data into the data structure, the job parameters into the data structure, and field characteristics into the data structure. The data structure may be a vector. The encoding may be performed as described in FIG. 2.

At operation 510, the method may include executing the job duration machine learning model using the data structure as an input. Executing may include performing calculations using the data structure and stored weights-based on prior training—of the job duration machine learning model.

At operation 512, the method may include after executing the job duration machine learning model, accessing an output of the job duration machine learning model, the output associated with the estimated duration of the agricultural job. The output may be a number or probability prediction such as discussed with respect to prediction 222 in FIG. 2.

At operation 514, the method may include transmitting the estimated duration and the job identifier to an agricultural job scheduling system. In various examples, the agricultural job scheduling system is the system that transmitted the request at operation 502.

In various examples, the method of FIG. 5 includes training the job duration machine learning model. For example, the method may include generating a training data set (e.g., training data 202) including data from a plurality of completed jobs for the job duration machine learning model. The data from a completed job in the plurality of completed jobs may include an area of a field in the completed job; a perimeter of the field; historical weather conditions of the field; and a field shape value of the field. The training may include encoding the data from the completed job into an input vector where components of the vector correspond to quantitative representations of the data from the completed job. For example, the encoding may be performed such as described for feature extraction 204. Then a training iteration (e.g., training iteration 208) of the job duration machine learning model may be executed with the input vector. A loss function value (e.g., loss function 206) may be calculated based on an output value of the job duration machine learning model after executing the training iteration and a recorded job duration for the completed job. The job duration machine learning model may be updated based on the loss function value.

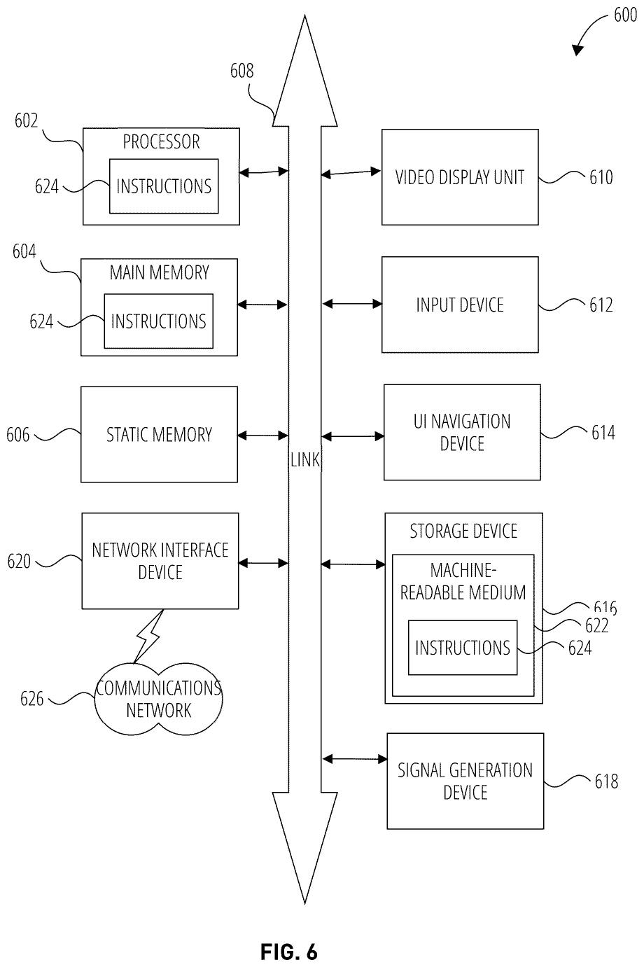

FIG. 6 is a block diagram illustrating a machine in the example form of computer system 600, within which a set or sequence of instructions may be executed to cause the machine to perform any of the methodologies discussed herein, according to an example embodiment. In alternative embodiments, the machine operates as a standalone device or may be connected (e.g., networked) to other machines. In a networked deployment, the machine may operate in the capacity of either a server or a client machine in server-client network environments, or it may act as a peer machine in peer-to-peer (or distributed) Network environments. The machine may be an onboard vehicle system, wearable device, personal computer (PC), tablet PC, hybrid tablet, personal digital assistant (PDA), mobile telephone, or any machine capable of executing instructions (sequential or otherwise) that specify actions to be taken by that machine. Further, while only a single machine is illustrated, the term “machine” includes any collection of machines that individually or jointly execute a set (or multiple sets) of instructions to perform any of the methodologies discussed herein. Similarly, the term “processor-based system” shall be taken to include any set of one or more machines that are controlled by or operated by a processor (e.g., a computer) to individually or jointly execute instructions to perform any one or more of the methodologies discussed herein Example computer system 600 includes at least one processor 602 (e.g., a central processing unit (CPU), a graphics processing unit (GPU) or both, processor cores, compute nodes, etc.), a main memory 604, and a static memory 606, which communicate with each other via a link 608. The computer system 600 may include a video display unit 610, an input device 612 (e.g., a keyboard), and a user interface UI navigation device 614 (e.g., a mouse). In an example, the video display unit 610, input device 612, and UI navigation device 614 are incorporated into a single device housing, such as a touchscreen display. The computer system 600 may additionally include a storage device 616 (e.g., a drive unit), a signal generation device 618 (e.g., a speaker), a network interface device 620, and one or more sensors (not shown), such as a global positioning system (GPS) sensor, compass, accelerometer, or other sensors.

The storage device 616 includes a machine-readable medium 622 on which one or more sets of data structures and instructions 624 (e.g., software) embodying or utilized by any of the methodologies or functions described herein. The instructions 624 may also reside, completely or at least partially, within the main memory 604, the static memory 606, or within the processor 602 during execution thereof by the computer system 600, with the main memory 604, the static memory 606, and the processor 602 also constituting machine-readable media.

While the machine-readable medium 622 is illustrated in an example embodiment to be a single medium, the term “machine-readable medium” may include a single medium or multiple media (e.g., a centralized or distributed database or associated caches and servers) that store the instructions 624. The term “machine-readable medium” shall also be taken to include any tangible medium that is capable of storing, encoding, or carrying instructions for execution by the machine and that causes the machine to perform any one or more of the methodologies of the present disclosure or that is capable of storing, encoding or carrying data structures utilized by or associated with such instructions. The term “machine-readable medium” includes, but is not limited to, solid-state memories and optical and magnetic media. Specific examples of machine-readable media include non-volatile memory, including but not limited to, by way of example, semiconductor memory devices (e.g., electrically programmable read-only memory (EPROM), electrically erasable programmable read-only memory (EEPROM)) and flash memory devices; magnetic disks such as internal hard disks and removable disks; magneto-optical disks; and CD-ROM and DVD-ROM disks. A computer-readable storage device may be a machine-readable medium 622 that excludes transitory signals.

The instructions 624 may be transmitted or received over a communications network 626 using a transmission medium via the network interface device 620 utilizing a transfer protocol (e.g., HTTP). Examples of communication networks include a local area network (LAN), a wide area network (WAN), the Internet, mobile telephone networks, plain old telephone (POTS) networks, and wireless data networks (e.g., Wi-Fi, 3G, 4G LTE/LTE-A, 5G or WiMAX networks). The term “transmission medium” shall be taken to include any intangible medium that is capable of storing, encoding, or carrying instructions for execution by the machine and includes digital or analog communications signals or other intangible mediums to facilitate communication of such software

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplate are examples using any combination or permutation of those elements shown or described (or one or more aspects thereof), either with respect to a particular example (or one or more aspects thereof), or with respect to other examples (or one or more aspects thereof) shown or described herein.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof), or with respect to other examples (or one or more aspects thereof) shown or described herein.

What is claimed is:

1. A method comprising:
receiving, using a processing unit, a request to calculate an estimated duration of an agricultural job, the request including an agricultural job identifier;
issuing, using the processing unit, a data retrieval command using the agricultural job identifier;
in response to the issuing, receiving field characteristics associated with a field, the field characteristics including a field shape value and an area of the field;
encoding, using the processing unit, the field characteristics into a data structure configured to be input into a job duration machine learning model;
executing, using the processing unit, the job duration machine learning model using the data structure as an input;
after executing the job duration machine learning model, accessing an output of the job duration machine learning model, the output associated with the estimated duration of the agricultural job; and
transmitting, using the processing unit, the estimated duration and the job identifier to an agricultural job scheduling system.

2. The method of claim 1, further comprising:
generating, using the processing unit, a training data set including data from a plurality of completed jobs for the job duration machine learning model, data from a completed job in the plurality of completed jobs including:
an area of a field in the completed job;
a perimeter of the field;
historical weather conditions of the field; and
a field shape value of the field.

3. The method of claim 2, further comprising:
encoding, using the processing unit, the data from the completed job into an input vector wherein components of the vector correspond to quantitative representations of the data from the completed job;
executing, using the processing unit, a training iteration of the job duration machine learning model with the input vector;
calculating a loss function value based on an output value of the job duration machine learning model after executing the training iteration and a recorded job duration for the completed job; and
updating the job duration machine learning model based on the loss function value.

4. The method of claim 1, further comprising:
presenting a user interface on a computing device, the user interface including an agricultural job identifier input configured to receive the agricultural job identifier.

5. The method of claim 4, further comprising:
updating the user interface to include an operation user interface element based on the received agricultural job identifier.

6. The method of claim 1, further comprising in response to the issuing:
executing an application programming interface call with a date and location associated with the agricultural job identifier;
receiving weather data in response to the executing; and
encoding the weather data into the data structure.

7. The method of claim 1, wherein the data structure is a vector.

8. The method of claim 1, further comprising in response to the issuing:
retrieving job parameters associated with the agricultural job identifier, the job parameters including an operation type and an estimated number of tender truck trips; and
encoding the job parameters into the data structure.

9. The method of claim 1, further comprising:
selecting the job duration machine learning model from a plurality of job duration machine learning models based on the area of the field.

10. The method of claim 1, wherein the request to calculate the estimated duration of the agricultural job is a request for an estimated duration of an agricultural job in progress.

11. The method of claim 1, wherein the request is received based on a trigger event.

12. The method of claim 11, wherein the trigger event is a change in an operational status of a piece of agricultural equipment associated with the agricultural job identifier.

13. The method of claim 11, wherein the trigger event is a change in predicted weather.

14. A system comprising:
a processing unit; and
a storage device comprising instructions, which when executed on the processing unit, configure the processing unit to perform operations comprising:
receiving a request to calculate an estimated duration of an agricultural job, the request including an agricultural job identifier;
issuing a data retrieval command using the agricultural job identifier;
in response to the issuing, receiving field characteristics associated with a field, the field characteristics including a field shape value and an area of the field;
encoding the field characteristics into a data structure configured to be input into a job duration machine learning model;
executing the job duration machine learning model using the data structure as an input;
after executing the job duration machine learning model, accessing an output of the job duration machine learning model, the output associated with the estimated duration of the agricultural job; and
transmitting the estimated duration and the job identifier to an agricultural job scheduling system.

15. The system of claim 14, wherein the instructions, which when executed by the processing unit, further configure the processing unit to perform operations comprising:
generating a training data set including data from a plurality of completed jobs for the job duration machine learning model, data from a completed job in the plurality of completed jobs including:
an area of a field in the completed job;
a perimeter of the field;
historical weather conditions of the field; and
a field shape value of the field.

16. The system of claim 15, wherein the instructions, which when executed by the processing unit, further configure the processing unit to perform operations comprising:
encoding the data from the completed job into an input vector wherein components of the vector correspond to quantitative representations of the data from the completed job;
executing a training iteration of the job duration machine learning model with the input vector;
calculating a loss function value based on an output value of the job duration machine learning model after executing the training iteration and a recorded job duration for the completed job; and
updating the job duration machine learning model based on the loss function value.

17. The system of claim 14, wherein the instructions, which when executed by the processing unit, further configure the processing unit to perform operations comprising:
presenting a user interface on a computing device, the user interface including an agricultural job identifier input configured to receive the agricultural job identifier.

18. The system of claim 17, wherein the instructions, which when executed by the processing unit, further configure the processing unit to perform operations comprising:
updating the user interface to include an operation user interface element based on the received agricultural job identifier.

19. The system of claim 14, wherein the instructions, which when executed by the processing unit, further configure the processing unit to perform operations comprising, in response to the issuing:
executing an application programming interface call with a date and location associated with the agricultural job identifier;
receiving weather data in response to the executing; and
encoding the weather data into the data structure.

20. A non-transitory computer-readable medium comprising instructions, which when executed by a processing unit, configure the processing unit to perform operations comprising:
receiving a request to calculate an estimated duration of an agricultural job, the request including an agricultural job identifier;
issuing a data retrieval command using the agricultural job identifier;
in response to the issuing, receiving field characteristics associated with a field, the field characteristics including a field shape value and an area of the field;
encoding the field characteristics into a data structure configured to be input into a job duration machine learning model;
executing the job duration machine learning model using the data structure as an input;
after executing the job duration machine learning model, accessing an output of the job duration machine learning model, the output associated with the estimated duration of the agricultural job; and
transmitting the estimated duration and the job identifier to an agricultural job scheduling system
